(19) United States
(12) Patent Application Publication
(10) Pub. No.: US 2008/0000873 A1
(43) Pub. Date: Jan. 3, 2008

(54) Device for Ethcing a Conductive Layer and Etching Method

(75) Inventors: Christophe Mazzara, Olivet (FR); Jaona Girard, Sevran (FR)

Correspondence Address: OBLON, SPIVAK, MCCLELLAND MAIER & NEUSTADT, P.C., 1940 DUKE STREET, ALEXANDRIA, VA, 22314, US

(73) Assignee: Saint-Gobain Glass France, Courbevoie (FR)

(21) Appl. No.: 11/577,357

(22) PCT Filed: Sep. 30, 2005
(86) PCT No.: PCT/FR05/50799

§ 371 Date: Apr. 17, 2007

(30) Foreign Application Priority Data
Oct. 19, 2004 (FR) 0452369

(51) Int. Cl. C25F 3/14

(52) U.S. Cl. 216/13; 156/345.21

(57) ABSTRACT

Device for chemically etching a layer (2) having electrical conduction properties on a transparent substrate (1), which device comprises support means (4) for supporting the substrate (1) and spray means (5) for spraying a solution, characterized in that the spray means (5) consists of a multiplicity of nozzles (50) that are placed above the substrate and are intended to simultaneously spray onto the layer to be etched at least two solutions (7, 8) either independently of each other or as a mixture mixed at the nozzles.

The invention relates to a device for etching layers deposited on transparent substrates of the glass substrate type, and more particularly layers that are at least slightly electrically conducting for the purpose of obtaining conducting elements, such as electrodes. The invention also relates to process for etching such conducting layers.

The invention is especially applicable to layers based on a doped metal oxide or based on a metal, and preferably to those which, through their intrinsic properties and their thicknesses, are transparent. However, the invention does not exclude opaque layers.

Many products based on glass substrates do actually require conducting elements in particular patterns with a good, or even very high, resolution. This is for example the case for the electrodes of the glass panel of field-emission displays of the flat-screen type, for the electrodes of photovoltaic cells, or for the arrays of conducting elements of heated glass or glass incorporating antennas.

Patent application EP 1 322 145 discloses a technique for chemically etching conducting metal oxide layers. A mask is deposited on the layer to be etched, the layer is etched in the regions not covered by the mask, by bringing these regions into contact with a solution at acid pH or at alkaline pH and by spraying powdered zinc or aluminum over the top; the layer is then cleaned by rinsing it with a solution based on water and/or organic solvents, and finally the mask is removed.

However, when this process is to be applied for applications requiring high etching resolution, the result is not optimal. Etching inhomogeneity is observed, in particular with the occurrence of the phenomenon of overetching i.e. the layer is etched even beneath the mask, which results in a distance between the electrodes that is not constant, making the substrate unusable.

Moreover, when the layer is based on tin-doped indium oxide (ITO), etching residues, such as ITO particles, appear, and simple rinsing with water is not sufficient to remove them. Rinsing with a specific detergent is required, which increases the manufacturing cost of the end-product.

It is therefore an object of the invention to remedy these drawbacks by proposing a novel and more effective process for chemically etching a layer having electrical conduction properties and requiring at least two etching solutions, and a device that is easy to use, in order to achieve the expected etching quality of the application in question and to allow industrial-scale production.

Within the context of the invention, the expression “layers having electrical conduction properties” is understood to mean layers having a resistivity of at most 4×10⁻² Ω·cm especially from about 4×10⁻³ to 4×10⁻⁴ Ω·cm at least. More particularly intended are layers with a resistivity of at most 1000Ω/□ preferably at most 500Ω/□, for layer thicknesses generally between 50 and 1000 nm.

Such layers are etched in order to obtain arrays of electrodes for various applications. However, it goes without saying that the etching technique of the invention can just as well be applied to layers that have little or no conductivity at all, for example layers of the dielectric or undoped metal oxide type, if it is of benefit to etch them, especially for decorative purposes.

According to the invention, the device for chemically etching a layer having electrical conduction properties on a transparent substrate comprises support means for supporting the substrate and spray means for spraying a solution, and is characterized in that the spray means consist of a multiplicity of nozzles that are placed above the substrate and are intended to simultaneously spray onto the layer to be etched at least two solutions, either independently of each other or as a mixture, mixed at the nozzles or upstream of the nozzles within a period of time before spraying that does not exceed thirty seconds.

Advantageously, the nozzles are supported by at least one elongate rail. Thus, the spray means may comprise at least one rail that extends along the longest dimension of the substrate and corresponds, lengthwise, approximately to this dimension. For example, they comprise at least two rails that extend over the longest dimension of the substrate and are spaced apart by a distance corresponding approximately to the shortest dimension of the substrate. The spray means may also comprise at least one rail that extends over the shortest dimension of the substrate and corresponds, lengthwise approximately to this dimension. Alternatively, the spray means comprise at least two rails that extend over the longest dimension of the substrate and are spaced apart by a distance corresponding approximately to the shortest dimension of the substrate, together with at least one additional rail that extends transversely to the two other rails.

In another embodiment, the nozzles are distributed so as to cover an area equivalent to the area of the substrate.

According to one features the nozzles spray at least one solution continuously or alternately.

According to another feature, the solutions may be sprayed onto any one substrate not in a single shot, but in delivery cycles. Thus, the two solutions may be sprayed over a period of time corresponding to a delivery cycle, the time between two cycles being for example spent spraying a single solution, either one of the two solutions or another solutions, such as a rinsing solution.

The nozzles may be supplied in various ways. Each rail includes a line for supplying a separate solution, the nozzles of any one rail delivering the same solution. As a variant, at least one rail has at least two lines for supplying respectively two separate solutions, which are respectively delivered to the multitude of nozzles, independently or concomitantly. It may also be envisaged for the two rails extending along the longest dimension of the substrate to be supplied with one and the same solution, whereas the transverse additional rail or rails are supplied with another, separate, solution.

The means for supporting the substrate are capable of running beneath the nozzles which are stationary, and/or the nozzles are capable of running above the substrate, which is in a stationary position or which is running. For example, the substrate is stationary, while certain nozzles for delivering a first solution are stationary nozzles and other nozzles for delivering a second solution are moving nozzles. Thus, it is possible to design stationary rails with nozzles that deliver a first solution, while at least one rail moves above the substrate, being capable of performing several back-and-forth movements and delivering the second solution via its nozzles.

According to another feature, the nozzles are placed at a height above the substrate of between one and a few tens of centimeters.

Preferably, the device includes a box that covers the nozzles and the substrate while the solutions are being sprayed.

The device of the invention is in particular used for a substrate that includes a tin-oxide-based layer to be etched and the nozzles simultaneously deliver a hydrochloric acid solution and a zinc-based solution.

The zinc-based solution is a solution in which the zinc particles are dispersed in water, the solution being continuously mixed by a rotating mechanical system as it is being supplied to the nozzles.

Moreover, the spray means are designed to deliver a rinsing solution, the spray means for the rinsing being stationary or moving above the substrate.

The etching device according to the invention can thus etch a very wide variety of layers, especially layers made of a doped metal oxide, such as fluorine-doped tin oxide SnO₂:F, arsenic-doped tin oxide SnO₂:As or antimony-doped tin oxide SnO₂:Sb, or those doped with other dopant metals from column VA of the Periodic Table. It can also etch layers based on tin-doped indium oxide ITO, or optionally metal layers, for example silver layers. These layers may be relatively thick, for example ranging from a few nanometers to a few hundred nanometers thick. Thus, the layers may have a thickness of 20 to 1000 nm, especially of at least 40 nm, for example of 200 to 380 nm.

In particular the device can be used for a substrate having a tin-oxide-based layer to be etched and the nozzles simultaneously deliver a hydrochloric acid solution and a zinc-based solution.

Another subject of the invention is a process for chemically etching a layer having electrical conduction properties, of the doped metal oxide type, on a transparent substrate of the glass type, which comprises at least one step of depositing a mask on the layer to be etched and a step of etching the layer in the regions not covered by the mask, which consists in bringing the regions of the layer into contact with a first solution at acid pH or alkaline pH and in spraying a second, zinc or aluminum, solution, characterized in that the first solution and the second solution are sprayed simultaneously onto the regions not covered by the mask.

Advantageously, the two solutions are sprayed simultaneously, either independently or simultaneously as a mixture, mixed at the time of spraying or within a period of time before spraying that does not exceed thirty seconds. This is because, if the two solutions are mixed, they must not be so too soon prior to spraying, the inventors having demonstrated that the etching takes place optimally on bringing the two solutions into contact with each other.

Using the device of the invention described above to carry out the process of the invention, it is possible for the two separate solutions to be sprayed simultaneously so as to mix them effectively when they are being deposited on the substrate, so as to ensure homogeneous etching.

Preferably, the two solutions are sprayed in the form of droplets. The droplets, which may for example be likened to a mist or to a more pronounced rain, have a fineness that depends in particular on the type of layer to be etched, on the thickness, on the distance separating the nozzles from the substrate and on the speed at which the substrate runs relative to the nozzles.

According to one feature, the process etches layers based on a doped metal oxide, especially layers based on tin oxide doped with fluorine arsenic or antimony, or based on tin-doped indium oxide (ITO).

The nature of the layer and its thickness are to be taken into account in order to adjust the concentrations of the corrosive etching solutions and the etching times (which are generally of the order of a few minutes at most). It turns out that the process according to the invention is particularly effective for etching layers based on SnO₂, especially SnO₂:F, which hitherto have been known to be, on the contrary, very “hard” and chemically resistant, and therefore difficult to etch. This thus opens up a much wider field of application for this type of layer, most particularly in electronics for making electrodes, instead of the usual ITO electrodes which are effective but generally require annealing treatments in order to obtain the required level of electrical conduction.

According to one feature, the zinc or aluminum of the solution is in suspension in one or more organic and/or aqueous solvents optionally provided with at least rheology-modifying additives.

The acid pH solution may comprise at least one aqueous or alcohol-type organic solvent and may preferably be based on an aqueous-alcoholic mixture of the water/ethanol or water/isopropanol type. This is because it has been found that adding alcohol to the water containing the acid makes it possible to better control the size of the hydrogen bubbles created on contact with the zinc, especially to reduce the size of these bubbles in order to etch the layer more “gently” (and thus avoid any risk of mask lifting off through the mechanical action of the H₂ bubbles). As a complement to or instead of the alcohol, this effect may also be obtained by adding suitable additives of the anionic, cationic or nonionic surfactant type. If the solution is at a basic pH, it comprises at least one aqueous, alcoholic or aqueous-alcoholic solvent, a strong base of the NaOH type and, optionally, additives of the surfactant type.

Of course, the process includes, after the etching step a cleaning treatment, in order to clean the substrate having the layer, and the removal of the mask.

For example, the cleaning may consist in rinsing the layer, by spraying the substrate with or immersing it in a solution based on water and/or organic solvents.

The mask may be removed in various ways. Without being limiting, a chemical process may firstly be chosen, in which the mask is dissolved in a suitable solvent, in particular an essentially organic solvent. This may be toluene, oil of turpentine, trichloromethane or butyl acetate.

If it is desired not to have to reprocess organic effluents, other processes of removal may be preferred Removal may be via an ultrasonic treatment, this being reserved however more for substrates of modest dimensions. Removal may also be via a heat treatment, for example by making the substrate run through a hot air knife—the knife softens the mask, which becomes liquid and is removed by the blast of air. Another solution consists in making the substrate pass through an oven, for example at a temperature of at least 250° C. and especially around 400 to 450° C., in order to burn the mask and destroy it. The advantage of such a treatment at very high temperature is that it may in fact be carried out concomitantly with another heat treatment that the substrate or one or other of the coatings with which said substrate is provided, has in any event to undergo, independently of the etching process. This is in particular the case in general for the glass substrates used in electronics, for example for those used in the construction of field-emission displays, in which the glass panels must undergo at least one high-temperature heat treatment for the purpose of dimensionally stabilizing them.

Another technique consists in softening the mask, by a heat treatment at moderate temperature in order to make it easier to remove, and then in peeling the mask off by pulling on it.

Yet another subject of the invention is the use of the device or the application of the process for the manufacture of conducting electrodes/elements in various industries. One may be the glass industry, for example for the purpose of manufacturing conducting arrays for resistance-heating glazing units or for glazing units that incorporate antennas. Another one may be the photovoltaic cell industry. Finally, it may be the electronics industry, for the purpose of manufacturing front or rear faces of field-emission displays of the flat screen type, such as plasma displays, or else touch screens, and more generally any type of screen/glazing capable of receiving, transmitting or emitting radiation, especially visible light.

The invention will be described below in greater detail with the aid of nonlimiting examples illustrated by the following figures:

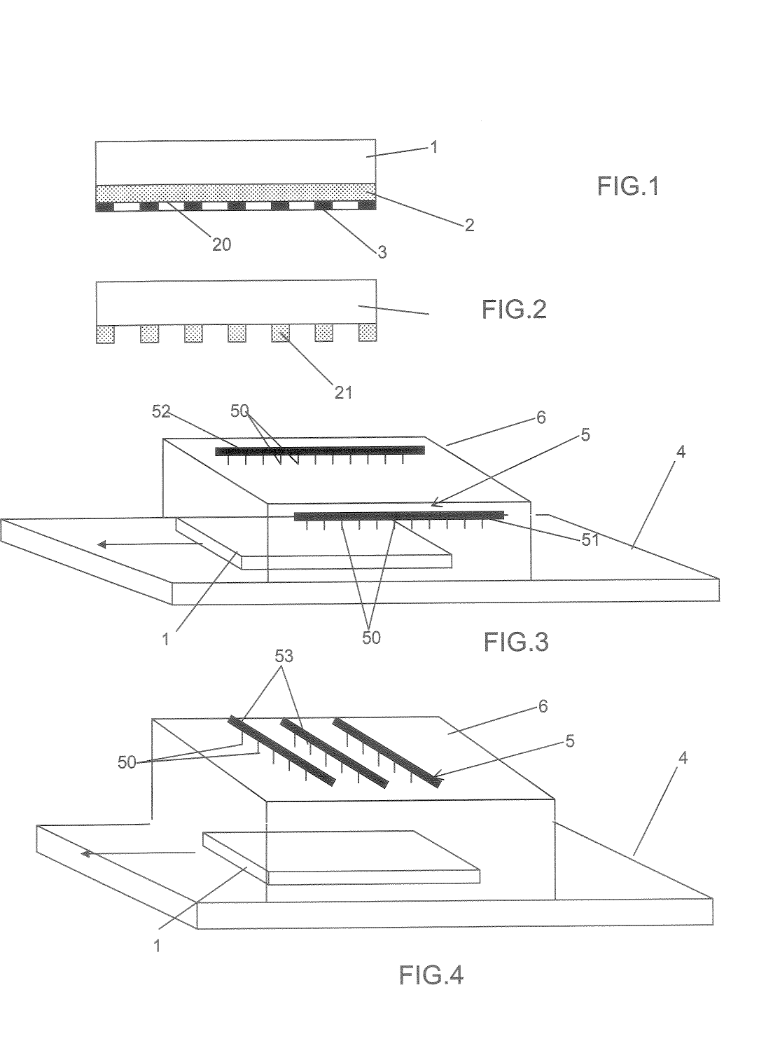

FIG. 1 is a sectional view of a substrate before etching;

FIG. 2 shows the substrate of FIG. 1 after etching; and

FIGS. 3 to 6 illustrate, respectively, four nonlimiting embodiments of a device of the invention.

Throughout the rest of the detailed description, it is accepted that the substrates considered by way of example are float glass substrates about 2.8 mm in thickness, for the purpose of forming the front and rear faces of field-emission displays of the plasma display type.

FIG. 1 illustrates a glass-type transparent substrate 1 that includes a layer 2 having electrical conduction properties and a patterned mask 3 deposited on the layer 2 to be etched the mask exposing uncovered regions 20 that are intended to be etched.

The objective is to carry out high-resolution etching of the layers in order to form in this case electrodes 21 (FIG. 2) in the form of parallel bands, for example 100 cm in length and 500 μm in width. These bands are for example spaced apart by 500 μm.

For plasma display applications, the electrodes to be formed may be parallel lines 300 μm in width spaced apart by 100 μm, or parallel lines having complex features on the scale of a pixel, which help to improve the plasma discharge and thus affect the brightness of the display, or else the electrodes may have a complex geometry, such as one consisting of shapes of the honeycomb type.

The deposited layer is for example of the doped metal oxide type, having a thickness of between 100 and 1000 nm in thickness depending on the type of application, which layer is deposited either by a CVD (Chemical Vapor Deposition) technique directly in a continuous manner, on the float glass ribbon, or subsequently on glass substrates that have been cut therefrom.

The steps of the etching process of the invention are given below.

The process starts with the glass substrate 1 cut and shaped appropriately, and coated with the layer 2.

Deposited directly over the entire layer is the photoresist resin-based mask 3, the thickness of which may in particular vary from 3 to 60 μm. The mask deposition process is well known to those skilled in the art—one embodiment is for example disclosed in United States patent U.S. Pat. No. 3,837,944. The mask 3 has a pattern, such as, in this case, one formed from parallel bands.

The layer 2 is to be etched in the exposed regions 20 not covered by the mask, which will also constitute, in their entirety, parallel bands.

Hence, two solutions are sprayed onto the substrate, by spraying them in the form of droplets, using the device that will be described below, so as to destroy the layer 2 in the unmasked regions 20. When two separate solutions are needed to perform the etching, for example for etching a layer made of fluorine-doped tin oxide (SnO₂:F), the device of the invention allows these two solutions to be sprayed simultaneously.

Next, the substrate is rinsed in a bath consisting for example of a mixture of water and possibly an alcohol, such as ethanol. In an alternative rinsing process the rinsing fluid may be sprayed from above the substrate, for example using nozzles similar to the nozzles 50, which may be stationary and/or able to move above the substrate, for example arranged on a moving rail performing back-and-forth movements.

Finally, the mask 3 is removed for example by immersing the substrate 1 in a bath of trichloromethane or by carrying out a heat treatment on the substrate in a suitable oven at 450° C. for 30 minutes, so as to obtain a layer that is etched with the features 21.

FIGS. 3, 4, 5 and 6 illustrate schematically four respective embodiments of devices according to the invention for carrying out the step of spraying the solutions needed for the etching operation. These embodiments are not limiting, and other embodiments of devices for spraying at least two solutions simultaneously according to the invention may be imagined.

One or more unetched substrates 1 are deposited on support means 4, capable of running and possibly stopping, such as a conveyor belt, so as to allow the substrate to run, or else to be momentarily positioned, beneath the spray means 5 intended to spray at least two solutions simultaneously. The spray means 5 are placed inside a protective box 6, which is open at its ends in order for the substrate to move progressively from the inlet of said box to its outlet.

It is also conceivable for the substrate to remain stationary, while the spray means move above the substrate, or else for the substrate, like the spray means, to move at speeds appropriate for performing the etching operation.

The spray means 5 consist of a multiplicity of nozzles 50 which in this case are, in the example of parallel lines to be etched, aligned and supported by one or more elongate rails. However, the nozzles may be supported in other ways and placed relative to the surface of the substrate in a different manner depending on the feature to be etched.

In a preferred embodiment, for which the substrate remains in a fixed position beneath the spray means 5, the nozzles are distributed over an area equivalent to the area of the substrate.

The outlet orifices of the nozzles may have various geometries, depending on the type of jet to be sprayed, for example a conical or flat jet, and various dimensions, depending on the desired fineness of the drops.

Advantageously, the nozzles can swivel in order to differentiate, from one nozzle to another in any one rail or in each of the rails, the direction in which the jet is sprayed onto the substrate.

The nozzles may be actuated alternately or continuously, depending on their position above the substrate. However, at least one plurality of nozzles from the entire arrangement, distributes at least the two solutions simultaneously.

One nozzle is either dedicated to just one solution, or else it is capable of delivering the mixture of the two solutions, mixing taking place at the nozzle so that the interaction of the two solutions takes place immediately prior to the mixture being sprayed onto the substrate, or else upstream of the nozzle but within a period of time that does not exceed thirty seconds before the mixture is delivered therethrough.

A person skilled in the art will adapt the various parameters involved in the process according to the type of layer to be etched and the thickness of the layer, namely the run speed of the substrate and/or of the nozzles, the height of the nozzles above the substrate, the orientation of the nozzles, the dimensions and the geometry of the nozzle orifices, the flowrate of the solutions to be sprayed etc.

In the embodiment shown in FIG. 3, the spray means 5 comprise at least two parallel elongate rails 51 and 52 that extend over the longest dimension of the substrate, in the direction in which it runs, and are separated by a distance approximately equivalent to the width of the substrate.

In the case of etching that requires two different solutions to be co-sprayed, the nozzles of a first rail may be supplied with a first solution, while the nozzles of the parallel rail are supplied with the second solution.

It is also conceivable for each rail to be supplied with the two solutions via two feedlines, each of the solutions arriving separately at the nozzles of the entire rail.

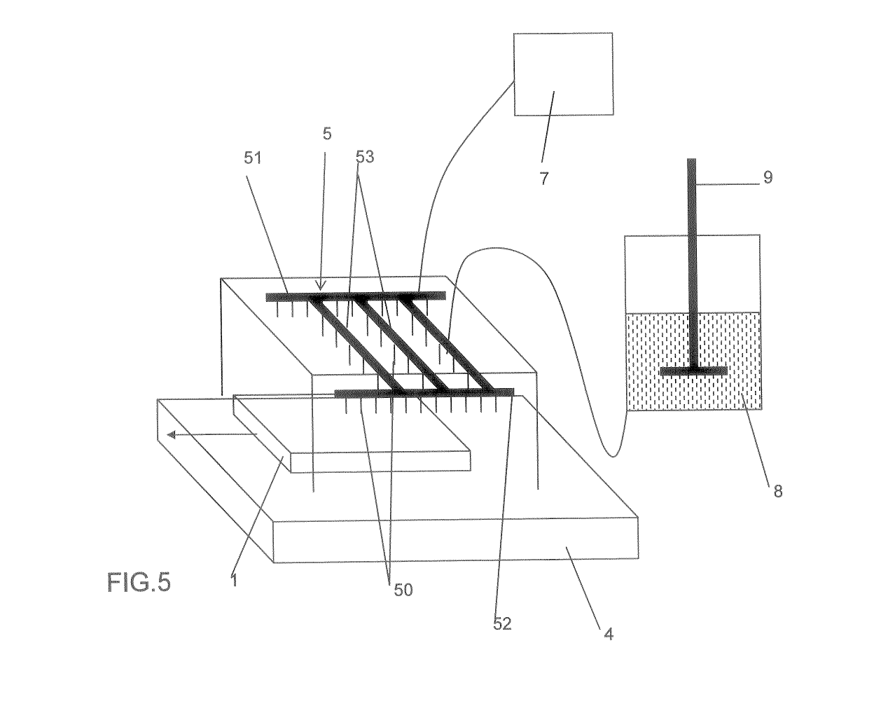

FIG. 4 illustrates another embodiment, which comprises a plurality of elongate rails 53 that are provided with nozzles 50 and arranged transversely to the direction in which the substrate runs and therefore in the direction of the shortest dimension of the substrate.

Depending on the spacing of the transverse rails 53, one or more rails are active for spraying the solutions over a sufficient area of running substrate.

To co-spray two solutions, it will be preferred to feed each rail with the two solutions via two separate feedlines, delivering them separately to the nozzles of the rail.

The third embodiment, shown in FIG. 5S comprises at least the two longitudinal rails 51 and 52 of FIG. 3 to which a plurality of additional, transverse, rails 53 have been added.

To co-spray two solutions, the first solution 7 is for example sprayed via the nozzles of the longitudinal rails 51 and 52, while the second solution 8 is sprayed via the nozzles of the transverse rails 53. A divided supply of the two solutions over a plurality of nozzles in any one rail may also be envisaged (this is not illustrated).

An SnO₂:F layer is for example a layer requiring two separate solutions to be sprayed, one an acid solution and the other a zinc solution. The embodiment shown in FIG. 5 may be preferred with separate supply of the two solutions into the longitudinal rails and transverse rails respectively.

The hydrochloric acid (HCl) solution 8 consists of water and HCl, preferably with a volume concentration of 1 to 2 mol/l of HCl, for example for etching a thickness of 200 nm.

The zinc solution 7 is formed by zinc powder (with particles of between 3 and 40 μm in size) dispersed in water. This mixture may be continuously stirred by a suitable rotating mechanical system 9, to be delivered to the rails for feeding the nozzles.

As a variant, the zinc mixture contains an organic or inorganic additive, for example a metal additive such as iron powder, or powdered silica, which allows the powder to remain dispersed. The mixture, being thus homogeneous, can be supplied to the nozzles.

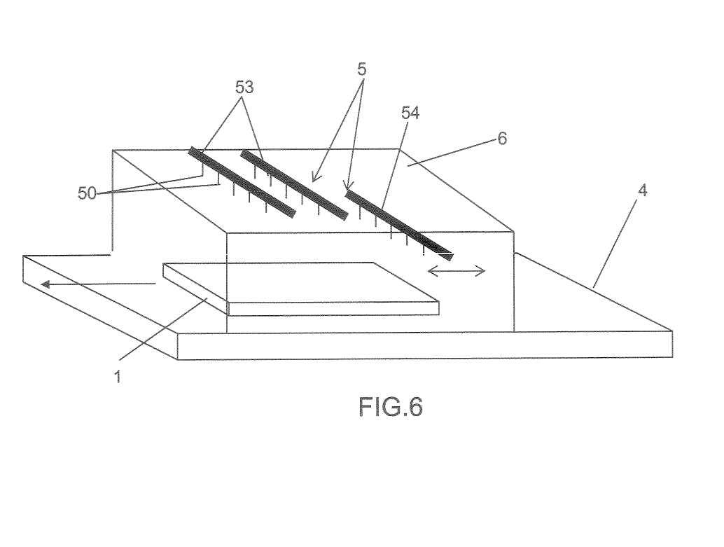

It is also possible to envisage an embodiment in which certain nozzles are stationary, while other nozzles are able to move above the substrate, which is preferably stopped in a fixed position at the moment of spraying (FIG. 6). The stationary nozzles, which deliver for example a first solution may for example be supported by at least one rail 53 that extends over the shortest dimension of the substrate. The moving nozzles, which deliver the second solution, may for example be supported by a rail 54 that also extends over the shortest dimension of the substrate and is made to undergo back-and-forth movements above the substrate by suitable guiding means, at a height substantially below the height of the stationary nozzles.

1: A device for chemically etching a layer (2) having electrical conduction properties on a transparent substrate (1), which device comprises support means (4) for supporting the substrate (1) and spray means (5) for spraying a solution, characterized in that the spray means (5) consist of a multiplicity of nozzles (50) that are placed above the substrate and are intended to simultaneously spray onto the layer to be etched at least two solutions (7, 8), either independently of each other or as a mixture, mixed at the nozzles or upstream of the nozzles within a period of time before spraying that does not exceed thirty seconds.

2: The device as claimed in claim 1, characterized in that the nozzles (50) are supported by at least one elongate rail (51, 52, 53).

3: The device as claimed in claim 2, characterized in that the spray means (5) comprise at least one rail (51) that extends over the longest dimension of the substrate and corresponds, lengthwise, approximately to this dimension.

4: The device as claimed in claim 2, characterized in that the spray means (5) comprise at least two rails (51, 52) that extend over the longest dimension of the substrate and are spaced apart by a distance corresponding approximately to the shortest dimension of the substrate.

5: The device as claimed in claim 2, characterized in that the spray means (5) comprise at least one rail (53) that extends over the shortest dimension of the substrate and corresponds, lengthwise, approximately to this dimension.

6: The device as claimed in claim 2, characterized in that the spray means (5) comprise at least two rails (51, 52) that extend over the longest dimension of the substrate and are spaced apart by a distance corresponding approximately to the shortest dimension of the substrate together with at least one additional rail (53) that extends transversely to the two other rails (51, 52).

7: The device as claimed in claim 1, characterized in that the nozzles (50) are distributed so as to cover at area equivalent to the area of the substrate.

8: The device as claimed in claim 1 characterized in that the nozzles (50) spray at least one solution continuously or alternately.

9: The device as claimed in claim 1, characterized in that the solutions are sprayed for any one substrate in delivery cycles.

10: The device as claimed in claim 2, characterized in that each rail includes a line for supplying a separate solution, the nozzles (50) of any one rail delivering the same solution.

11: The device as claimed in claim 2, characterized in that at least one rail has at least two lines for supplying respectively two separate solutions, which are respectively delivered to the multitude of nozzles (50), independently or concomitantly.

12: The device as claimed in claim 6, characterized in that the two rails (51, 52) extending along the longest dimension of the substrate are supplied with one and the same solution, whereas the transverse additional rail or rails (53) are supplied with another, separate, solution.

13: The device as claimed in claim 1, characterized in that the means (4) for supporting the substrate are capable of running beneath the nozzles (50) which are stationary, and/or the nozzles (50) are capable of running above the substrate, which is in a stationary position or which is running.

14: The device as claimed in claim 1, characterized in that the substrate is stationary, while certain nozzles for delivering a first solution are stationary nozzles and other nozzles for delivering a second solution are moving nozzles.

15: The device as claimed in claim 1, characterized in that the nozzles (50) are placed at a height above the substrate of between one and a few tens of centimeters.

16: The device as claimed in claim 1, characterized in that it includes a box (6) that covers the nozzles and the substrate while the solutions are being sprayed.

17: The device as claimed in, claim 1, characterized in that it is used for a substrate that includes a tin-oxide-based layer to be etched and the nozzles (50) simultaneously deliver a hydrochloric acid solution and a zinc-based solution.

18: The device as claimed in claim 17, characterized in that the zinc-based solution is a solution in which the zinc particles are dispersed in water, the solution being continuously mixed by a rotating mechanical system (9) as it is being supplied to the nozzles (50).

19: The device as claimed in claim 1, characterized in that the spray means (5) are designed to deliver a rinsing solution, the spray means for the rinsing being stationary or moving above the substrate.

20: A process for chemically etching a layer (2) having electrical conduction properties, of the doped metal oxide type, on a transparent substrate (1) of the glass type, which comprises at least one step of depositing a mask (3) on the layer to be etched and a step of etching the layer (2) in the regions (2′) not covered by the mask, which consists in bringing the regions (2′) of the layer into contact with a first solution (7) at acid pH or alkaline pH and in spraying a second, zinc or aluminum, solution (8), characterized in that the first solution (7) and the second solution (8) are sprayed simultaneously onto the regions (2′) not covered by the mask.

21: The process as claimed in claim 20, characterized in that the two solutions are sprayed simultaneously, either independently or simultaneously as a mixture mixed at the time of spraying or within a period of time before spraying that does not exceed thirty seconds.

22: The process as claimed in claim 20, characterized in that the two solutions are sprayed in the form of droplets.

23: The process as claimed in claim 20, characterized in that it etches layers based on a doped metal oxide, especially layers based on tin oxide doped with fluorine, arsenic or antimony, or based on tin-doped indium oxide (ITO).

24: The process as claimed in claim 20, characterized in that the zinc or aluminum of the solution is in suspension in one or more organic and/or aqueous solvents optionally provided with at least rheology-modifying additives.

25: The process as claimed in claim 20, characterized in that the first solution at acid pH or at basic pH comprises at least one aqueous, alcoholic or aqueous-alcoholic solvent, a strong acid of the HCl type or a strong base of the NaOH type respectively, and optionally additives of the surfactant type.

26: The process as claimed in claim 20, characterized in that it includes, after the etching step, a leaning treatment, in order to clean the substrate (1) having the layer (2), and the removal of the mask (3).

27: The process as claimed in claim 20, characterized in that the cleaning phase consists in rinsing the layer (2), by spraying the substrate (1) with or immersing it in a solution based on water and/or organic solvents.

28: The process as claimed in claim 26, characterized in that the mask (3) is removed by dissolving it in a suitable essentially organic solvent, or by an ultrasonic treatment, or by softening the mask and then peeling it off by pulling on it, or by a heat treatment.

29: The manufacture of conducting electrodes/elements in the glass industry, in the electronics industry, and in the photovoltaic cell industry which uses the device as claimed in claim 1.

30. The manufacture of conducting electrodes/elements in the glass industry, in the electronics industry, flat screen type, such as plasma displays, or for touch and in the photovoltaic cell industry which uses the process as claimed in claim 20.
